(19) United States
(12) Patent Application Publication
(10) Pub. No.: US 2013/0146351 A1
(43) Pub. Date: Jun. 13, 2013

(54) ELECTRONIC DEVICE ENCLOSURE WITH MOUNTING ASSEMBLY

(71) Applicants: YUN-LUNG CHEN, Tu-Cheng (TW); CHUNG CHAI, Tu-Cheng (TW); DA-LONG SUN, Wuhan City (CN)

(72) Inventors: YUN-LUNG CHEN, Tu-Cheng (TW); CHUNG CHAI, Tu-Cheng (TW); DA-LONG SUN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/565,781

(22) Filed: Aug. 2, 2012

(30) Foreign Application Priority Data
Dec. 8, 2011 (CN) 201110405462.8

(51) Int. Cl. E05C 3/14; H05K 5/00

(52) U.S. Cl. 174/520; 292/202; 292/228

(57) ABSTRACT

A mounting assembly includes a latching mechanism, an engaging member, and an actuating member. The latching mechanism is pivotably secured to a base. The engaging member is secured to a cover. The actuating member is pivotably secured to the engaging member. The actuating member is rotatable relative to the engaging member, between a locked position and an unlocked position; when the actuating member is in the locked position, the latching mechanism is engaged with the engaging member to secure the cover to the base, and when the actuating member is in the unlocked position the latching mechanism is rotated to disengage it from the engaging member, and the actuating member biases the latching mechanism to rotate.

### BACKGROUND

1. Technical Field

The present disclosure relates to electronic device enclosures, and particularly to an electronic device enclosure with a mounting assembly.

2. Description of Related Art

Electronic device enclosures, such as a personal computer case, may include a base and a cover. The base comprises a bottom plate, two sidewalls, a rear plate, and a front plate, the two sidewalls extending from opposite edges of the bottom plate. The rear plate and the front plate extend from the other opposing edges of the bottom plate. The two sidewalls, the rear plate and the front plate cooperatively surround an opening. The cover is configured to be secured to the base for covering the opening with a plurality of screws. Using screws is very laborious and time-consuming.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure comprising a base and a cover.

FIG. 2 is an exploded view of the base and a latching mechanism of FIG. 1.

FIG. 3 is an enlarged view of the circled portion III of FIG. 1.

FIG. 4 is an exploded view of the cover, the engaging member, the actuating member and the resilient member of FIG. 1.

FIG. 5 is an assembled view of the items of FIG. 4.

FIG. 6 is assembled view of the electronic device enclosure of FIG. 1.

FIG. 7 is a cross-sectional view of FIG. 6, taken along line VII-VII, the mounting mechanism being located in a locked position.

FIG. 8 is similar to FIG. 7, the mounting mechanism is in a unlocked position.

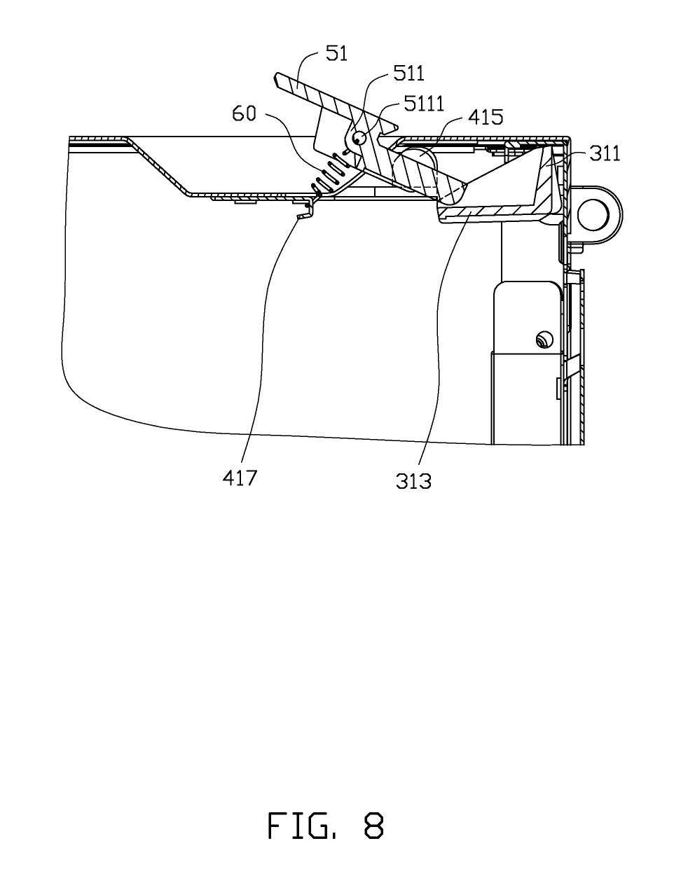

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

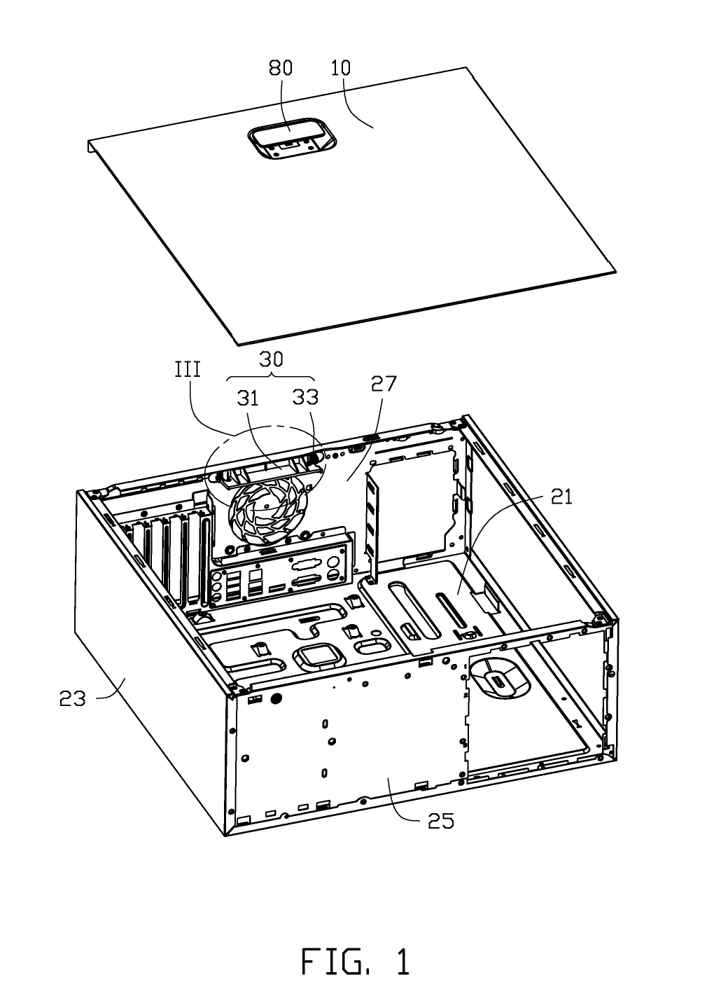

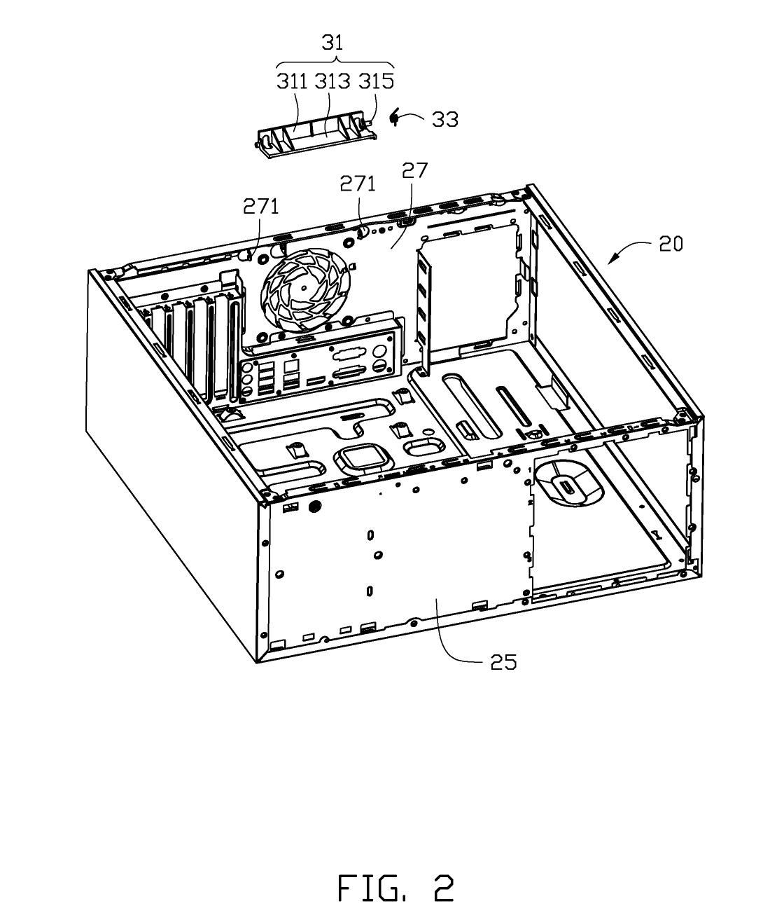

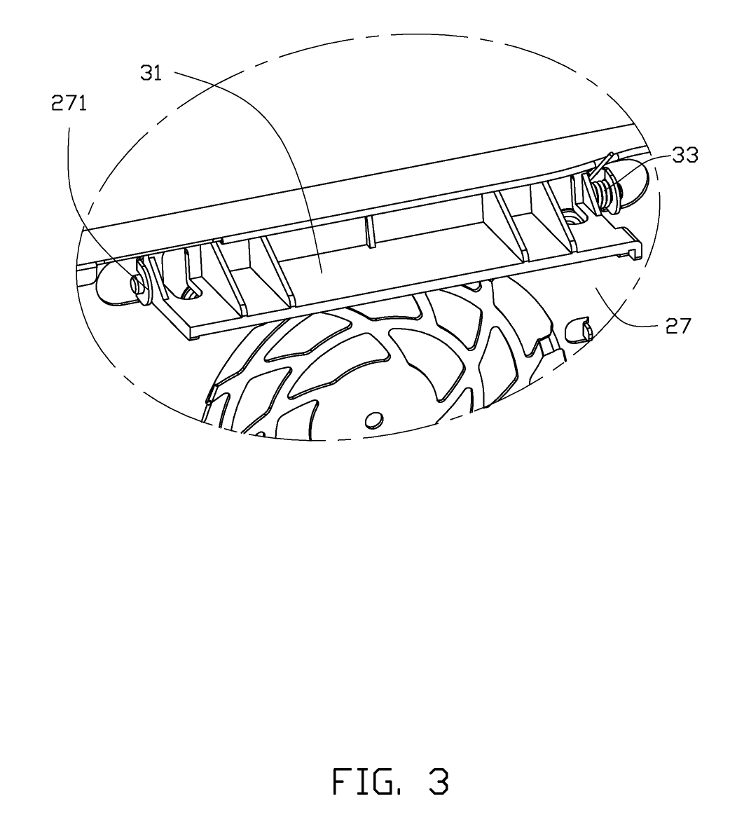

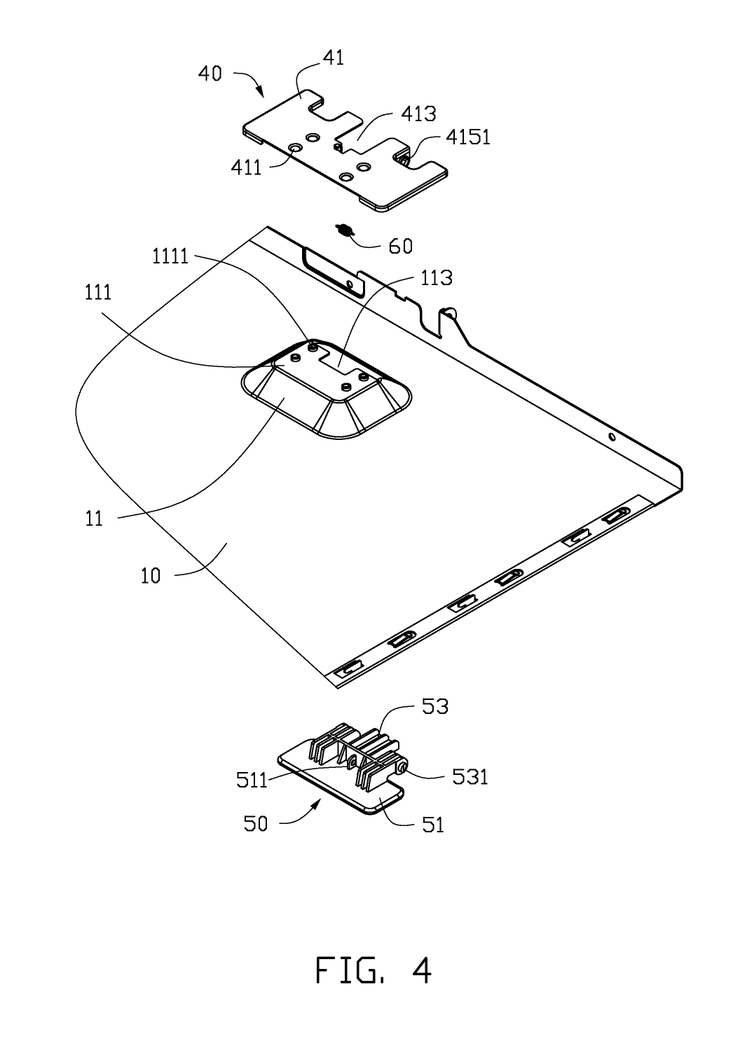

Referring to FIGS. 1-4, an electronic device enclosure in accordance with an embodiment includes a cover 10, a base 20, a latching mechanism 30 pivotably secured to the base 20, and a mounting mechanism 80 attached to the cover 10.

A hollow portion 11 is located on the cover 10. The hollow portion 11 comprises a bottom portion 111 and defines a cutout 113. Four installation posts 1111 are located on outer surface of the bottom portion 111.

The base 20 includes a bottom plate 21, two sidewalls 23, a front plate 25, and a rear plate 27. The two sidewalls 23 extend from opposite edges of the bottom plate 21. The front plate 25 and the rear plate 27 extend from the other opposing edges of the bottom plate 21. In one embodiment, the two sidewalls 23 are parallel to each other and perpendicular to the bottom plate 21, and the front plate 25 is parallel to the rear plate 27 and perpendicular to the bottom plate 21. Two retaining tabs 271 extend inwards from an inner surface of the rear plate 27. Each of the two retaining tabs 271 defines a pivot hole. The two sidewalls 23, the front plate 25 and the rear plate 27 cooperatively surround an opening.

The latching mechanism 30 includes a latching member 31 and a torsion spring 33. The latching member 31 includes a blocking board 311 and a latching board 313 substantially perpendicularly connected to the blocking board 311. Two pivot portions 315 are located on opposite ends of the blocking board 311. The torsion spring 33 is fitted around one of two pivot portions 315.

The mounting mechanism 80 includes an engaging member 40 secured to the cover 10, an actuating member 50 pivotably secured to the engaging member 40, and a resilient member 60.

The engaging member 40 includes an engaging board 41. Four installation holes 411 are defined in the engaging board 41 for the insertion of the four installation posts 1111. A gap 413 is defined in the engaging board 41 adjacent to the four installation holes 411. Two positioning tabs 415 extend from opposite side edges of the gap 413. Each of the two positioning tabs 415 defines a rotating hole 4151. A hook 417, adjacent to the four installation holes 411, extends downwards from an inner edge of the gap 413.

The actuating member 50 includes an operating board 51 and a pressing portion 53 located on one side of the operating board 51. The operating board 51 is received in the hollow portion 11. A securing tab 551 is located on the operating board 51. A securing hole 5111 is defined in the securing tab 511. Two rotating posts 531 are located on opposite sides of the pressing portion 53.

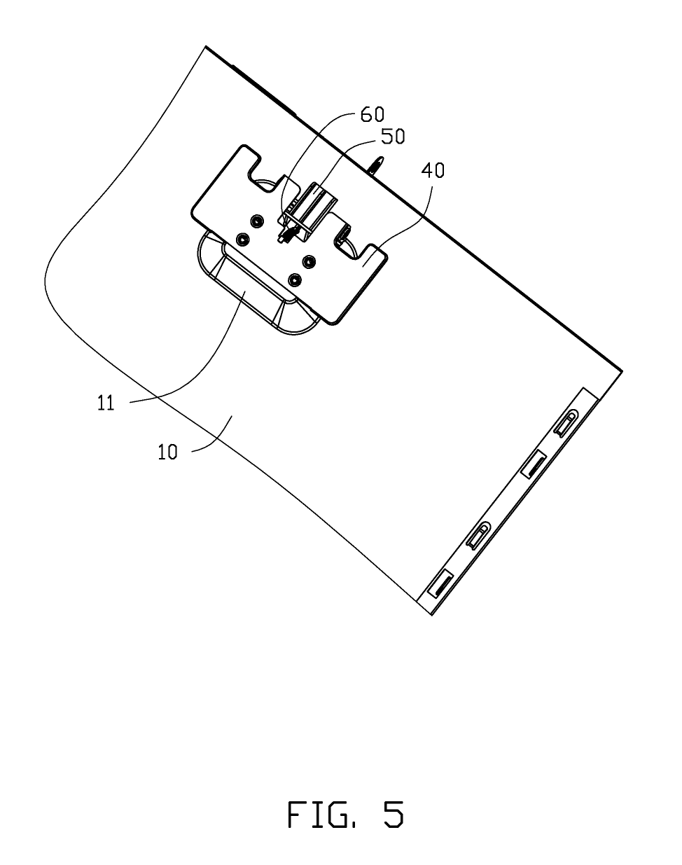

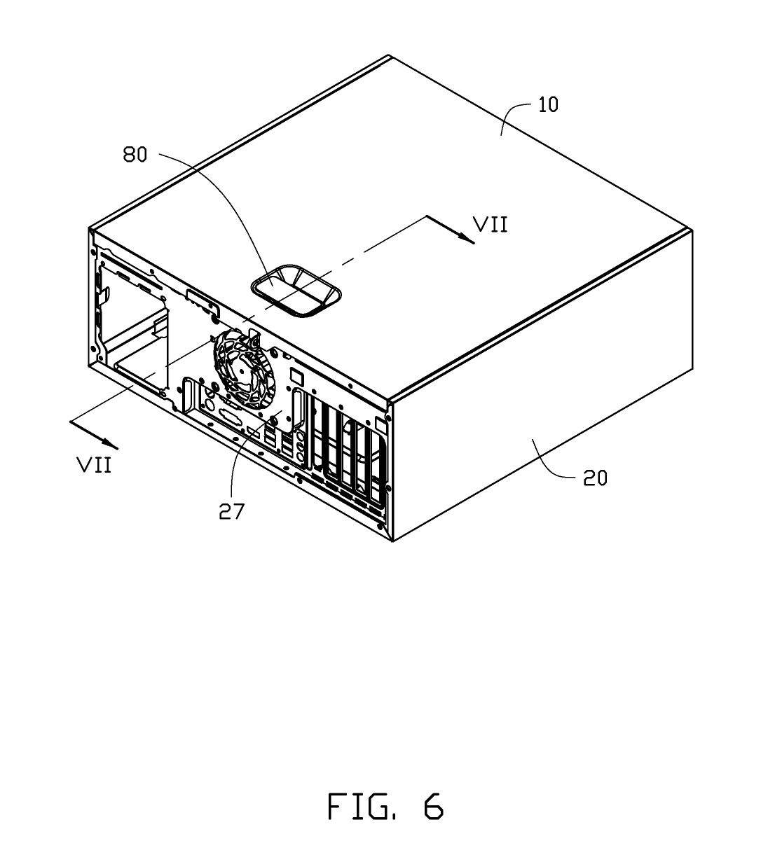

Referring to FIG. 5-6, in assembly of the latching mechanism 30, the torsion spring 33 is fitted around one of the two pivot portions 315. The two pivot portions 315 are inserted into the pivot hole of the two retaining tabs 271. On end of the torsion spring 33 engages with the latching member 31, and the other end of the torsion spring 33 engages with the rear plate 27.

The four installation posts 1111 are inserted into the four installation holes 411 to secure the engaging member 40 to the cover 10. The pressing portion 53 is inserted into the cutout 113 of the cover 10. The two rotating posts 531 of the actuating member 50 are engaged in the two rotating holes 4151 of the engaging member 40. In this way, the operating board 51 of the actuating member 50 is received in the hollow portion 11. The pressing portion 53 is located on an inner side of the cover 10. A first end of the resilient member 60 is engaged in the securing hole 5111 of the actuating member 50, and a second end opposite to the first end of the resilient member 60 is engaged with the hook 417.

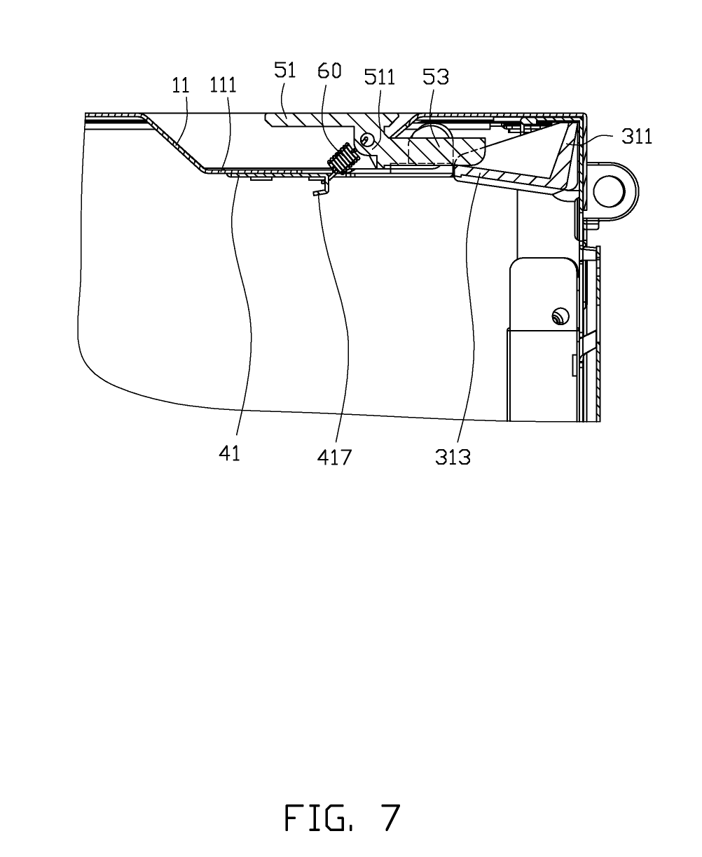

Referring to FIG. 7, in assembly of the cover 10, the operating board 51 of the actuating member 50 is pulled to rotate the pressing portion 53 along a first direction away from the cover 10. The resilient member 60 is elastically stretched along the operating board 51. The pressing portion 53 presses the latching board 313 and the torsion spring 33 is twisted, until the cover 10 covers the opening. The blocking board 311 is substantially parallel to the rear plate 27. The operating board 51 is released. The resilient member 60 elastically returns to rotate the pressing portion 53 along a second direction opposite to the first direction. The actuating member 50 is in a locked position, where the pressing portion 53 is disengaged from the latching board 313 of the latching member 31. The torsion spring 33 urges the latching member 31 to rotate, until the latching board 313 blocks the engaging board 41, preventing the cover 10 from moving along a direction perpendicular to the rear plate 27. An acute angle is defined between the rear plate 27 and the blocking board 311.

Referring to FIG. 7, in disassembly of the cover 10, the operating board 51 is pulled to rotate the pressing portion 53 along the first direction. The actuating member 50 is in an unlocked position, wherein the pressing portion 53 rotates the latching board 313 to disengage from the engaging board 41. The cover 10 is thus easily detached from the base 20.

Even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting assembly comprising:
a latching mechanism, the latching mechanism configured to be pivotably secured to a base;
an engaging member, the engaging member configured to be secured to a cover; and
an actuating member, the actuating member pivotably secured to the engaging member;
wherein the actuating member is rotatable relative to the engaging member between a locked position and an unlocked position; when the actuating member is in the locked position, the latching mechanism is engaged with the engaging member to secure the cover to the base; and when the actuating member is in the unlocked position the latching mechanism is rotatable to disengage from the engaging member, and the actuating member biases the latching mechanism to rotate.

2. The mounting assembly of claim 1, further comprising a resilient member, wherein the resilient member connects the engaging member to the actuating member, and the resilient member is elastically deformable to rotate the actuating member from the unlocked position to the locked position.

3. The mounting assembly of claim 2, wherein the actuating member comprises a securing tab with a securing hole, the engaging member comprises an engaging board, and a hook is located on the engaging board; and a first end of the resilient member is engaged in the securing hole, and a second end, opposite to the first end of the resilient member, is engaged with the hook.

4. The mounting assembly of claim 3, wherein the actuating member further comprise a pressing portion connected to the securing tab, two rotating posts are located on the pressing portion; and two positioning tabs, respectively defining a rotating hole, are located on the engaging board, and the two rotating posts are rotatably engaged in the rotating hole of the two positioning tabs.

5. The mounting assembly of claim 1, wherein the latching mechanism comprises a latching member; the latching member is rotatable between a first position and a second position; when the latching member is located on the first position, the latching member blocks the engaging member; and when the latching member is located on the second position, the latching member is disengaged from the engaging member.

6. The mounting assembly of claim 5, wherein the latching mechanism further comprises a torsion spring, the latching member is rotatable from the second position to the first position, and the torsion spring basis the latching member towards the engaging member.

7. The mounting assembly of claim 6, wherein two pivot portions are located on the latching member, and the two pivot portions are respectively engaged in two pivot holes defined in the base.

8. The mounting assembly of claim 7, wherein the torsion spring surrounds one of the two pivot portions, one end of the torsion spring is engaged with the latching member, and another end of the torsion spring is engaged with the base.

9. The mounting assembly of claim 5, wherein the latching member comprises a latching board and a blocking board connected to the latching board; when the actuating member is in the locked position, the latching board is engaged with the engaging member, the blocking board abut the base; and when the actuating member is in the unlocked position, the latching board is disengaged with the engaging member, and the blocking board is disengaged from the base.

10. The mounting assembly of claim 9, wherein the blocking board is substantially perpendicular to the latching board.

11. An electronic device enclosure comprising:
a base, the base defining an opening;
a cover; a latching mechanism, the latching mechanism pivotably secured to the base;
an engaging member, the engaging member secured to the cover; and
an actuating member, the actuating member pivotably secured to the engaging member;
wherein the actuating member is rotatable relative to the engaging member between a locked position and an unlocked position; when the actuating member is in the locked position, the latching mechanism is engaged with the engaging member to secure the cover to the base; when the actuating member is in the unlocked position, the latching mechanism is rotatable to disengage from the engaging member to unfasten the cover, and the actuating member is configured to bias the latching mechanism to rotate.

12. The electronic device enclosure of claim 11, further comprising a resilient member, wherein the resilient member connects the engaging member to the actuating member, and the resilient member is elastically deformable to rotate the actuating member from the unlocked position to the locked position.

13. The electronic device enclosure of claim 12, wherein the actuating member comprises a securing tab with a securing hole, the engaging member comprises an engaging board, and a hook is located on the engaging board; a first end of the resilient member is engaged in the securing hole, and a second end opposite to the first end of the resilient member is engaged with the hook.

14. The electronic device enclosure of claim 13, wherein the actuating member further comprise a pressing portion connected to the securing tab, two rotating posts are located on the pressing portion; two positioning tabs, respectively defining a rotating hole, are located on the engaging board, and the two rotating posts are rotatably engaged in the rotating hole of the two positioning tabs.

15. The electronic device enclosure of claim 14, wherein a hollow portion, defining a cutout, is located on the cover, the actuating member further comprises an operating board; the operating board is received in the hollow portion, and the pressing portion is engaged in the cutout.

16. The electronic device enclosure of claim 15, wherein the hollow portion comprises a bottom portion, the engaging board is attached on the bottom portion.

17. The electronic device enclosure of claim 11, wherein the latching mechanism comprising a latching member and a torsion spring; the latching member is rotatable between a first position and a second position, when the latching member is located on the first position, the latching member blocks the engaging member; when the latching member is located on the second position, the latching member is disengaged from the engaging member, and the torsion spring biases the latching member to rotate from the second position to the first position.

18. The electronic device enclosure of claim 17, wherein two pivot portions are located on the latching member, and the two pivot portions are respectively engaged in two pivot holes defined in the base.

19. The electronic device enclosure of claim 18, wherein the torsion spring surrounds one of the two pivot portions, one end of the torsion spring is engaged with the latching member, and another end of the torsion spring is engaged with the base.

20. The electronic device enclosure of claim 17, wherein the latching member comprises a latching board and a blocking board connected to the latching board, the base comprises a rear plate; when the actuating member is in the locked position, the latching board is engaged with the engaging member, and an acute angle is defined between the rear plate and the blocking board; and when the actuating member is in the unlocked position, the latching board is disengaged with the engaging member, and the blocking board is substantially parallel to the rear plate.
